(19) United States
(12) Patent Application Publication
(10) Pub. No.: US 2024/0363306 A1
(43) Pub. Date: Oct. 31, 2024

(54) CHARGED PARTICLE BEAM DEVICE

(71) Applicant: Hitachi High-Tech Corporation, Tokyo (JP)

(72) Inventors: Minami SHOUJI, Tokyo (JP); Natsuki TSUNO, Tokyo (JP); Hiroya OHTA, Tokyo (JP); Daisuke BIZEN, Tokyo (JP); Hajime KAWANO, Tokyo (JP)

(73) Assignee: Hitachi High-Tech Corporation, Tokyo (JP)

(21) Appl. No.: 18/771,126

(22) Filed: Jul. 12, 2024

Related U.S. Application Data
(63) Continuation of application No. 17/610,908, filed on Nov. 12, 2021, now abandoned.

(51) Int. Cl. H01J 37/22; H01J 37/244

(52) U.S. Cl. CPC H01J 37/222; H01J 37/226; H01J 37/244

(57) ABSTRACT

An object of the invention is to provide a charged particle beam apparatus capable of acquiring an observation image having a high contrast in a sample whose light absorption characteristic depends on a light wavelength. The charged particle beam apparatus according to the invention irradiates the sample with light, generates an observation image of the sample, changes an irradiation intensity per unit time of the light, and then generates a plurality of the observation images having different contrasts.

This application is a continuation of U.S. patent application Ser. No. 17/610,908, filed on Nov. 12, 2021, which claims the benefit of International Patent Application No. PCT/JP2019/020065, filed May 21, 2019, the entire contents of which are incorporated herein by reference.

### TECHNICAL FIELD

The present invention relates to a charged particle beam apparatus that irradiates a sample with a charged particle beam.

### BACKGROUND ART

In a manufacturing process of a semiconductor device, in-line inspection and measurement by using a scanning electron microscope (SEM) is an important inspection item for a purpose of improving a yield. In particular, a low voltage SEM (LV SEM) using an electron beam having an acceleration voltage of several kV or less is extremely useful in inspection and measurement of a two-dimensional shape such as a resist pattern in a lithography process and a gate pattern in a previous process because a penetration depth of the electron beam is shallow and an image having rich surface information can be acquired. However, since organic materials such as a resist and an anti-reflection film used in the lithography process have compositions similar to each other, or silicon-based semiconductor materials constituting a transistor have compositions similar to each other, it is difficult to obtain a difference in secondary electron emission from the materials. Since a sample made of such materials has a low image contrast of the SEM, visibility of an ultrafine pattern or a defect of a semiconductor device is reduced. As a visibility improving method of the SEM, a method for adjusting observation conditions such as an acceleration voltage and an irradiation current and a technique for discriminating energy of electrons emitted from a sample are known, but a resolution and an imaging speed are problems depending on the conditions.

PTL 1 discloses a technique for controlling an image contrast of an SEM by irradiating an observation region of the SEM with light. Since an exciting carrier is generated by light irradiation, conductivity of a semiconductor or an insulator changes. A difference in conductivity between materials is reflected in a potential contrast of an SEM image. A conduction failure location of a semiconductor device or the like can be detected by controlling the potential contrast of the SEM by the light irradiation.

PTL 2 discloses a method for controlling an image contrast of an SEM by selecting a light wavelength for a sample configured with a plurality of layers, focusing on a difference in light absorption characteristics depending on a wavelength of light to be emitted.

### CITATION LIST

### Patent Literature

PTL 1: JP-A-2003-151483
PTL 2: Japanese Patent Application No. 2010-536656

### SUMMARY OF INVENTION

### Technical Problem

In both PTL 1 and PTL 2, the image contrast of the SEM is controlled according to the difference in the absorption characteristics of materials depending on the light wavelength. Both can enhance the image contrast in the materials having a large difference in wavelength dependence of the absorption characteristics. However, similar wavelength dependence of the absorption characteristics exists in many materials of similar types such as silicon materials having different dopant types and densities, or organic materials having similar compositions. In a sample composed of these materials, it may be difficult to obtain a sufficient difference in the absorption characteristics.

The invention has been made in consideration of the above problem, and an object of the invention is to provide a charged particle beam apparatus capable of acquiring an observation image having a high contrast even in a sample whose light absorption characteristic depends on a light wavelength.

### Solution to Problem

A charged particle beam apparatus according to the invention irradiates a sample with light and generates an observation image of the sample, and generates a plurality of the observation images having different contrasts by changing an irradiation intensity per unit time of the light.

### Advantageous Effect

According to the charged particle beam apparatus according to the invention, an amount of secondary electrons emitted from the sample can be controlled by adjusting a light irradiation intensity per unit time according to a light absorption characteristic. As a result, contrasts of the observation images even in materials of similar types having similar light absorption characteristics with respect to a light wavelength can be enhanced.

### BRIEF DESCRIPTION OF DRAWINGS

FIG. 1 is a configuration diagram of a charged particle beam apparatus 1 according to a first embodiment.

FIG. 2 is a configuration example of an absorption characteristic measuring unit 13.

FIG. 3 is a flowchart illustrating a procedure in which the charged particle beam apparatus 1 acquires an observation image of a sample 8.

FIG. 4 is a graph showing a relation between a light irradiation intensity Ir per unit time and a light absorption intensity Ia.

FIG. 5 is a graph showing a relation between the light irradiation intensity Ir per unit time and an emission amount of secondary electrons.

FIG. 6 is an example of a GUI 61 displayed by an image display unit 25.

FIG. 7 is an example of a cross-sectional view of the sample 8.

FIG. 8 is an example of observation images acquired under three conditions of a light irradiation intensity per unit time.

FIG. 9 is a configuration diagram of the charged particle beam apparatus 1 according to a second embodiment.

FIG. 10 is a flowchart illustrating a procedure in which the charged particle beam apparatus 1 acquires an observation image of the sample 8.

FIG. 11 is a configuration diagram of a pulse laser 10 and a light intensity adjusting unit 11 in the second embodiment.

FIG. 12 is an example of a relation between a light absorption characteristic measured in S1001 and a light irradiation intensity per unit time.

FIG. 13 is an example of a cross-sectional view of the sample 8.

FIG. 14 is a graph showing a relation of a correction amount ΔC of a secondary electron detection signal with respect to the light irradiation intensity per unit time in the second embodiment.

FIG. 15 is an example of observation images acquired under three conditions of the light irradiation intensity per unit time.

FIG. 16 is a time chart showing an electron beam irradiation timing/a pulse laser irradiation timing/a secondary electron detection timing, respectively.

FIG. 17 is an example of the GUI 61 displayed by the image display unit 25 in a third embodiment.

FIG. 18 is an example of a cross-sectional view of the sample 8.

FIG. 19 is an example of observation images acquired by electron beams under irradiation conditions.

FIG. 20 is a configuration example of an absorption characteristic measuring unit 13.

FIG. 21 is a configuration example of the absorption characteristic measuring unit 13.

FIG. 22 is an example of observation images acquired under three conditions of the light irradiation intensity per unit time.

FIG. 23 is a configuration diagram of the charged particle beam apparatus 1 according to a fifth embodiment.

FIG. 24 is a graph showing an energy distribution of the secondary electrons when a light pulse is emitted with various light irradiation intensities.

FIG. 25 is an example of observation images acquired by an energy filter 231 under two conditions of the light irradiation intensity per unit time.

FIG. 26 is a configuration diagram of the charged particle beam apparatus 1 according to a sixth embodiment.

FIG. 27 is an example of a cross-sectional view of the sample 8.

FIG. 28 is an example of observation images acquired under two conditions of the light irradiation intensity.

### DESCRIPTION OF EMBODIMENTS

### <Regarding Basic Principle of Invention>

Hereinafter, first, a basic principle of the invention is described, and then specific embodiments of the invention are described. The invention irradiates a sample to be observed with light to excite a carrier inside the sample. In this case, the sample is in an excited state. An emission amount of secondary electrons in the excited state increases according to a light absorption amount. Meanwhile, when photoelectrons are emitted from the sample by light irradiation, the sample is in a depleted state where electrons are deficient. An emission amount of the secondary electrons in the depleted state decreases according to the light absorption amount.

An increase and decrease amount ΔS of the secondary electrons due to the light irradiation is expressed by Formula 1. A represents a light absorption amount, and z represents a distance to a light intrusion direction.

$$\begin{matrix}[ Formula 1 ] & \\ Δ S ∝ \pm \int dA / dz \cdot dz & ( 1 )\end{matrix}$$

An intrusion direction dependence of the light absorption amount dA/dz is expressed by Formula 2. α1 to α3 represent absorption coefficients of a material, α1 represents a linear absorption term, and α2 and α3 represent a second-order and third-order non-linear absorption terms. Here, the terms up to the third-order are described, but higher-order terms are also confirmed. Ir represents a light irradiation intensity per unit time on the sample. Parameters that control the light irradiation intensity per unit time include an average output of a pulse laser, an energy per pulse, a peak intensity per pulse, a pulse width of the pulse laser, the number of light pulses to be emitted per unit time, a frequency of the light pulse, an area of a light spot, a light wavelength, a polarization, and the like.

$$\begin{matrix}[ Formula 2 ] & \\ dA / dz = \{ {α}_{1} \cdot {I}_{r} + {α}_{2 \cdot } {I}_{r}^{2} + {α}_{3} \cdot {I}_{r}^{3} & ( 2 )\end{matrix}$$

When the light irradiation intensity is low, a linear absorption term based on single photon absorption is dominant, and if the light wavelength is in an absorption band of the material, the sample absorbs light and comes into an excited state. In the excited state, an emission efficiency of the secondary electrons becomes high. When the light irradiation intensity is high, a non-linear absorption term based on multiphoton absorption is dominant, and even if the light wavelength is not in the absorption band of the material, the sample absorbs light and changes from the excited state to a depleted state where photoelectrons are emitted. In the depleted state, the emission efficiency of the secondary electrons becomes low. That is, the emission amount of the secondary electrons can be controlled by controlling an absorption characteristic as the single photon absorption or the multiphoton absorption according to the light irradiation intensity. Photophysical property parameters for confirming non-linear absorption include an absorption coefficient, a reflection coefficient, a polarization modulation, a wavelength modulation, a photoelectron emission, and the like.

The invention provides a charged particle beam apparatus in which the above principle is used, and even in materials having similar absorption characteristics with respect to light wavelengths, a highly visible observation image in which a contrast of patterns or defects is enhanced can be acquired by adjusting an irradiation intensity per unit time of light.

### First Embodiment

A first embodiment of the invention describes a charged particle beam apparatus that irradiates an observation region with a pulse laser whose light irradiation intensity per unit time is controlled according to a light absorption characteristic of a sample, and enhances an observation image contrast.

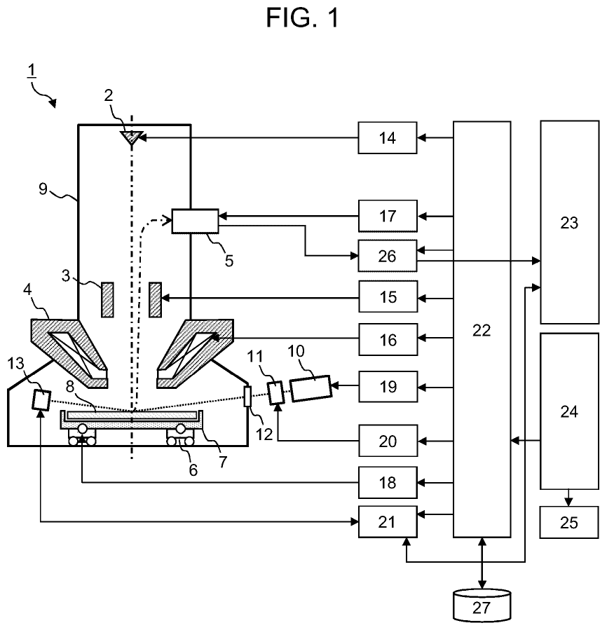

FIG. 1 is a configuration diagram of a charged particle beam apparatus 1 according to the first embodiment. The charged particle beam apparatus 1 is configured as a scanning electron microscope that irradiates a sample 8 with an electron beam (primary charged particles) to acquire an observation image of the sample 8. The charged particle beam apparatus 1 includes an electro-optical system, a stage mechanical system, a light pulse irradiation system, a light absorption characteristic measurement system, a control system, an image processing system, and an operation system. A storage device 27 will be described later.

The electro-optical system includes an electron gun 2, a deflector 3, an electron lens 4, and an electron detector 5. The stage mechanical system includes an XYZ stage 6 and a sample holder 7. An inside of a housing 9 is controlled to a high vacuum, and is provided with the electro-optical system and the stage mechanical system. The light pulse irradiation system includes a pulse laser 10 and a light intensity adjusting unit 11. Light is emitted to the sample 8 through a light pulse introduction unit 12 provided in the housing 9. An absorption characteristic measuring unit 13 detects a light pulse reflected from the sample 8.

The control system includes an electron gun control unit 14, a deflection signal control unit 15, an electron lens control unit 16, a detector control unit 17, a stage position control unit 18, a pulse laser control unit 19, a light intensity adjustment control unit 20, an absorption characteristic measurement control unit 21, a control transmission unit 22, and a detection signal acquisition unit 26. The control transmission unit 22 writes and controls a control value to each of the control units based on input information input from an operation interface 23. The image processing system includes an image forming unit 24 and an image display unit 25.

An electron beam accelerated by the electron gun 2 is focused by the electron lens 4 and emitted to the sample 8. The deflector 3 controls an irradiation position of the electron beam on the sample 8. The electron detector 5 detects emission electrons (secondary charged particles) emitted from the sample 8 by irradiating the sample 8 with the electron beam. The operation interface 23 is a functional unit for a user to specify and input an acceleration voltage, an irradiation current, a deflection condition, a detection sampling condition, an electron lens condition, and the like.

A light pulse emitted from the pulse laser 10 is emitted to a position on the sample 8 irradiated with the electron beam. The light intensity adjusting unit 11 is a device that controls an irradiation intensity per unit time of a light pulse laser. The electron detector 5 detects secondary electrons emitted from the sample 8. The secondary electrons include both low-energy emission electrons from a sample and high-energy backscattered electrons. The image forming unit 24 forms an SEM image (observation image) of the sample 8 using a detection signal detected by the electron detector 5, and the image display unit 25 displays the image.

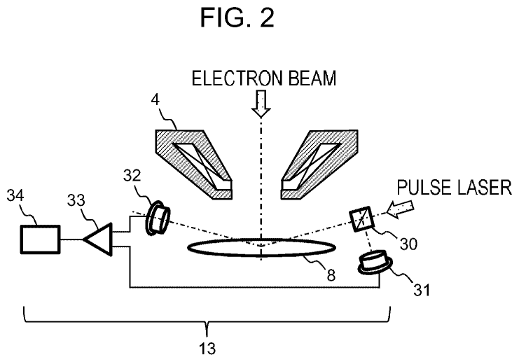

FIG. 2 is a configuration example of the absorption characteristic measuring unit 13. A pulse laser whose irradiation intensity is adjusted by the light intensity adjusting unit 11 is split by a beam splitter 30 before being emitted to the sample 8. An irradiation light detector 31 detects a signal according to an intensity of light emitted to the sample 8. In this case, the light intensity is calibrated according to a split ratio of the beam splitter 30. The pulse laser emitted to the sample 8 is reflected in the sample 8, and a reflection light detector 32 installed opposite to the beam splitter detects a signal according to the light intensity. A subtractor 33 obtains a difference signal of the signals detected by the irradiation light detector 31 and the reflection light detector 32. A signal detector 34 digitizes a light absorption intensity based on the difference signal.

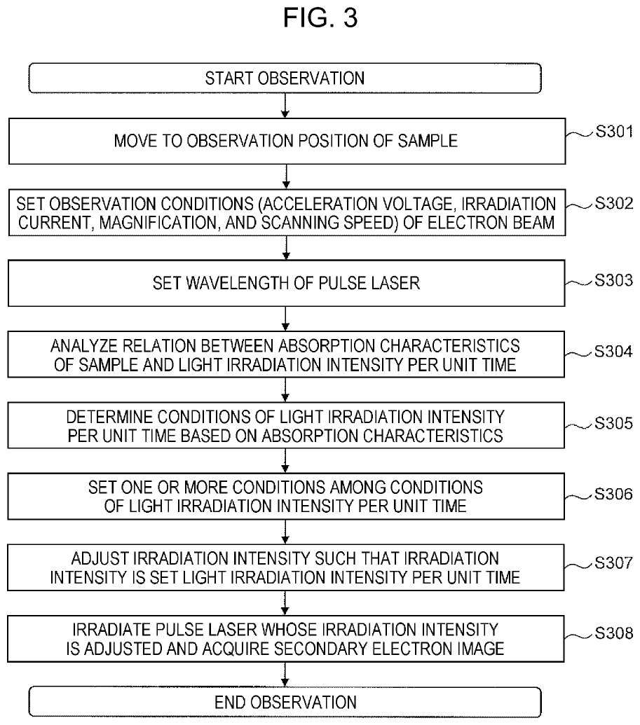

FIG. 3 is a flowchart illustrating a procedure in which the charged particle beam apparatus 1 acquires the observation image of the sample 8. Hereinafter, each step in FIG. 3 will be described.

### (FIG. 3: Steps S301 to S303)

The stage mechanical system moves the sample 8 to an observation position (S301). The control transmission unit 22 sets the acceleration voltage, the irradiation current, a magnification, and a scanning time as basic electron beam observation conditions according to the specification and input from the operation interface 23 (S302). The pulse laser control unit 19 sets a wavelength of the pulse laser (S303). The laser wavelength is desired to be set based on a wavelength band in which the sample 8 absorbs light.

### (FIG. 3: Step S304)

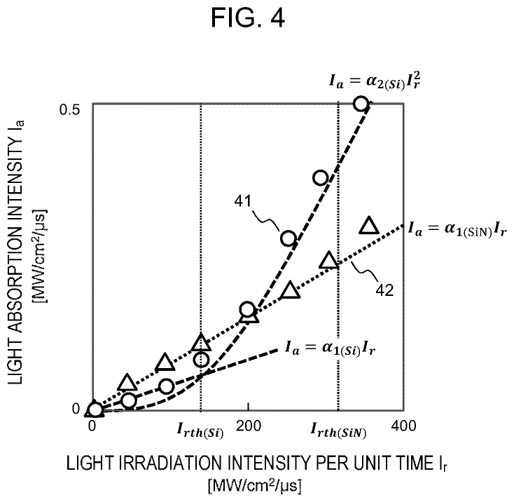

The control transmission unit 22 measures a light absorption characteristic of the sample 8 while changing an irradiation intensity per unit time of light. The light irradiation intensity is controlled by the light intensity adjusting unit 11. A light absorption measurement is performed by the absorption characteristic measuring unit 13. The control transmission unit 22 stores, in the storage device 27, data describing a correspondence relation between the light irradiation intensity and the light absorption characteristic based on the measurement result. An example of the correspondence relation in this step is described with reference to FIG. 4 described later.

### (FIG. 3: Step S305)

The control transmission unit 22 sets a threshold of the light irradiation intensity per unit time based on the result of step S304. The threshold here can be determined based on, for example, which of the light absorption characteristics of Formula 2 is dominant, the linear absorption term (α1) or the non-linear absorption term (from α2). A specific example of a criteria for determining the threshold is described with reference to FIG. 4 described later.

### (FIG. 3: Steps S304 and S305: Supplement No. 1)

In this flowchart, an analysis result in S304 is stored in the storage device 27 and used, and the correspondence relation between the light irradiation intensity and the light absorption characteristic under various conditions is analyzed in advance and a result thereof can be stored in the storage device 27 as a database. As a result, it is unnecessary to carry out steps S304 and S305 every time the observation image is acquired.

(FIG. 3: steps S304 and S305: Supplement No. 2)

The storage device 27 can be configured with an appropriate device that stores the measurement result and the correspondence relation. For example, if the measurement result and the correspondence relation are stored as a database in advance and used, the storage device 27 can be configured with a non-volatile storage device. If the measurement result and the correspondence relation are acquired each time this flowchart is executed, the storage device 27 can be configured with a memory device or the like that temporarily stores the measurement result and the correspondence relation. These devices may be combined.

### (FIG. 3: Steps S306 to S308)

The control transmission unit 22 sets one or more light irradiation intensities as an observation condition according to the results of S304 and S305 (S306). The observation condition described here does not have to be the threshold itself set in S305, and may be an appropriate value close to the threshold as described later. The control transmission unit 22 adjusts the irradiation intensity by the light intensity adjusting unit 11 such that the irradiation intensity is the light irradiation intensity set as the observation condition (S307). The control transmission unit 22 irradiates the sample 8 with a light pulse and an electron beam whose irradiation intensities per unit time are adjusted, and acquires an observation image by the image forming unit 24 (S308).

FIG. 4 is a graph showing a relation between a light irradiation intensity Ir per unit time and a light absorption intensity Ia. In S304, the relation as illustrated in FIG. 4 is measured. Here, the relation between the light absorption characteristic and the light irradiation intensity per unit time when the sample 8 is composed of silicon (Si) and silicon nitride (SiN) is illustrated. In an absorption characteristic 41 of silicon, it can be seen that the light absorption intensity Ia changes from a linear characteristic to a non-linear characteristic when the light irradiation intensity Ir per unit time is about 150 MW/cm2/μs. In an absorption characteristic 42 of silicon nitride, a linear characteristic is maintained until the light irradiation intensity Ir becomes about 300 MW/cm2/μs.

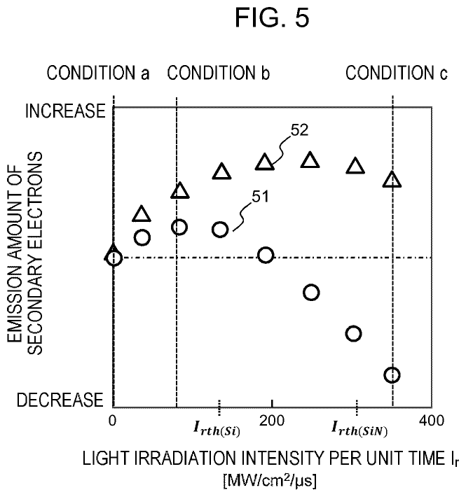

In S305, the control transmission unit 22 can set an irradiation intensity at which the absorption characteristic 41 (Si) changes from linear to non-linear as a threshold Irth (Si), and can set an irradiation intensity at which the absorption characteristic 42 (SiN) changes from linear to non-linear as a threshold Irth (SiN). Significances of these thresholds are described with reference to FIG. 5.

FIG. 5 is a graph showing a relation between the light irradiation intensity Ir per unit time and an emission amount of the secondary electrons. As an amount of Ir increases, an emission amount of secondary electrons 51 of silicon increases, and gradually decreases when Ir reaches about 150 MW/cm2/μs or more. An emission amount of secondary electrons 52 of silicon nitride increases to about 300 MW/cm2/μs. In the present description, the phenomenon of increase and decrease in the emission amount of secondary electrons is referred to as a modulation effect of secondary electrons. The present inventors have discovered that the modulation effect occurs when the absorption characteristic changes from linear to non-linear. Therefore, in FIG. 5, the irradiation intensities at which the emission amounts of secondary electrons start to decrease correspond to the threshold Irth (Si) and the threshold Irth (SiN), respectively.

In order to enhance the contrast of the observation image for each of the materials, it is desirable to set the observation condition such that the emission amounts of secondary electrons differ greatly for the materials. This corresponds to a large difference between the emission amounts of secondary electrons 51 and 52 in FIG. 5. It is considered that such an observation condition with a high contrast generates at the irradiation intensities closing to boundaries which are the thresholds at which the emission amounts of secondary electrons start to decrease. Therefore, in FIG. 5, three observation conditions for comparing the contrast are set: condition a (0 MW/cm2/μs), condition b (70 MW/cm2/μs), and condition c (350 MW/cm2/μs), respectively. An example of observation images using these conditions will be described later.

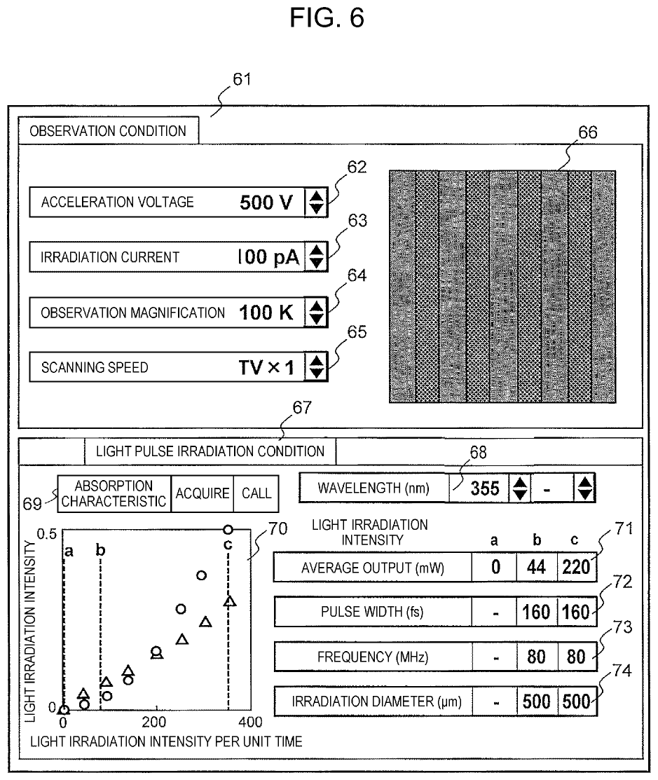

FIG. 6 is an example of a graphical user interface (GUI) 61 displayed by the image display unit 25. Basic observation conditions of an acceleration voltage 62, an irradiation current 63, a magnification 64, and a scanning speed 65 can be set on the GUI 61. The image display unit 66 displays the observation image. An irradiation condition setting unit 67 includes (a) a wavelength setting unit 68 that sets a wavelength of a light pulse, (b) an absorption characteristic analysis unit 69 that acquires (or calls from a database) an absorption characteristic of a sample, (c) an absorption characteristic display unit 70 that displays the absorption characteristic, and (d) an irradiation intensity setting unit that sets an average output 71 of a light pulse, a pulse width 72, a frequency 73 of the light pulse, and an irradiation diameter 74 of the light pulse based on the conditions of the light irradiation intensity per unit time determined on the absorption characteristic display unit 70. In FIG. 6, two wavelengths can be selected as the wavelengths of the light pulse. Further, three conditions can be set as the conditions of the light irradiation intensity per unit time. Other parameters can also be set on the GUI 61.

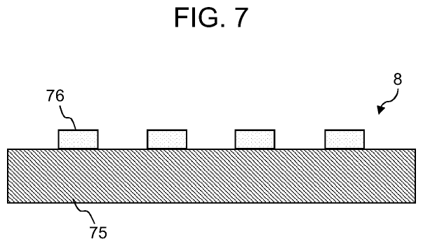

FIG. 7 is an example of a cross-sectional view of the sample 8. Here, as illustrated in FIG. 4, an example composed of silicon 75 and silicon nitride 76 is shown. A thin film of the silicon nitride 76 is patterned in a line on the silicon 75. Observation conditions of an electron beam include an acceleration voltage of 0.5 kV, an irradiation current of 100 pA, an observation magnification of 100 K times, and a scanning speed of a TV scanning speed. A wavelength of a light pulse is 355 nm. As illustrated in FIG. 5, the light irradiation intensities per unit time are set to 0 MW/cm2/μs, 70 MW/cm2/μs, and 350 MW/cm2/μs. Light average outputs are 0 mW, 44 mW, and 220 mW for irradiation intensities, respectively.

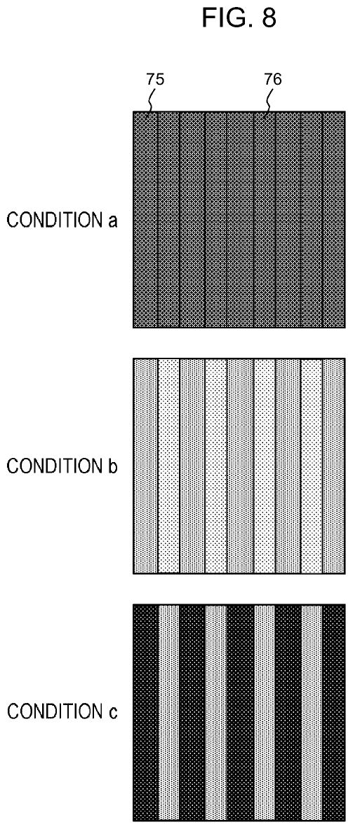

FIG. 8 is an example of observation images acquired under three conditions of the light irradiation intensity per unit time. The conditions a to c have been described in FIG. 5. In the observation image acquired under the condition a, the silicon 75 and the silicon nitride 76 show the same image brightness, and visibility of a pattern is low. In the observation image acquired under the condition b, a high image brightness is obtained for both the silicon 75 and the silicon nitride 76, and the visibility of the pattern is high. In the observation image acquired under the condition c, the image brightness of the silicon 75 is low, and the image brightness of the silicon nitride 76 is high. It can be seen that the observation image acquired under the condition c can obtain the highest contrast.

The same effect can be obtained even if the charged particle beam apparatus 1 according to the first embodiment is implemented in a retarding system in which a voltage is applied to the XYZ stage 6, the sample holder 7, and the sample 8 to reduce an electron energy applied to the sample.

### Overview of First Embodiment

The charged particle beam apparatus 1 according to the first embodiment can control the amount of the secondary electrons emitted from the sample 8 by adjusting the irradiation intensity of actually emitted light per unit time according to the light absorption characteristic that depends on the light irradiation intensity per unit time. Therefore, even if the materials are of the same type and have similar absorption characteristics with respect to the light wavelength, the observation image contrast can be enhanced, and thus the visibility of the defect and the pattern of the sample 8 is improved.

### Second Embodiment

When the sample 8 is irradiated with light, photoelectrons may be emitted from the sample 8. The photoelectrons act as noise for the secondary electrons. Therefore, in the second embodiment of the invention, a configuration example for removing an influence of the photoelectrons on a detection result of the secondary electrons is described.

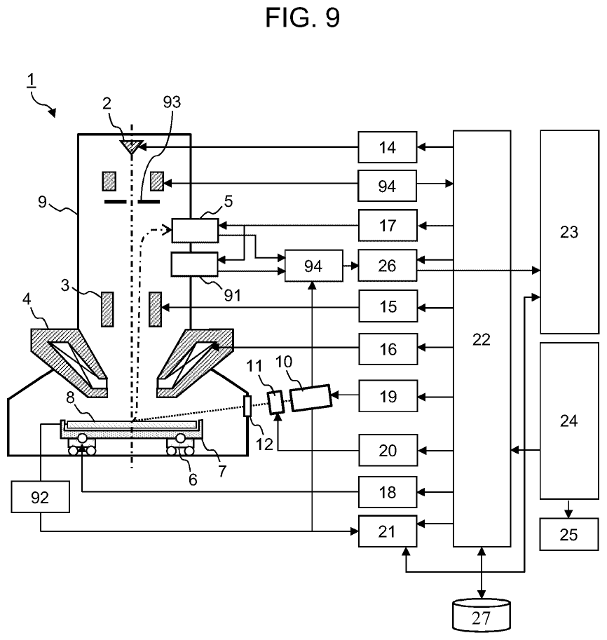

FIG. 9 is a configuration diagram of the charged particle beam apparatus 1 according to the second embodiment. The charged particle beam apparatus 1 according to the second embodiment includes the configuration described in the first embodiment, and further includes a photoelectron detector 91, a photovoltaic current measuring device 92, a circuit breaker 93, and a signal corrector 94. The photoelectron detector 91 detects the photoelectrons from the sample 8 by light pulse irradiation. The photovoltaic current measuring device 92 measures a current flowing through the sample 8 by irradiating the sample 8 with the light. The circuit breaker 93 has a function of blocking an electron beam. The signal corrector 94 corrects a detection signal of the secondary electrons or brightness of an observation image based on the detection signal of the photoelectrons which is detected by the photoelectron detector 91. Since other configurations are the same as those in the first embodiment, a difference will be mainly described below.

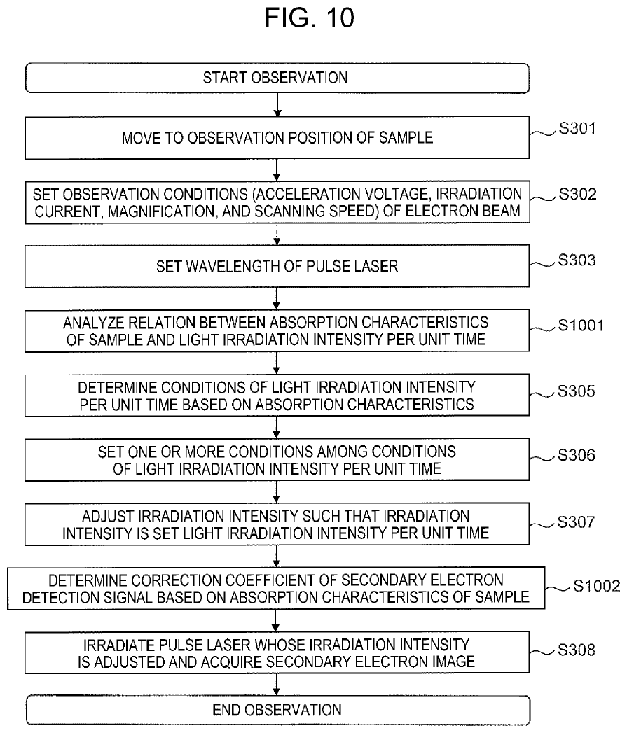

FIG. 10 is a flowchart illustrating a procedure in which the charged particle beam apparatus 1 acquires an observation image of the sample 8. In the flowchart of FIG. 10, S1002 is added between S307 and S308 in addition to the flowchart illustrated in FIG. 3, and S304 is replaced with S1001. Other steps are the same as those in FIG. 3.

### (FIG. 10: Step S1001)

The control transmission unit 22 measures the light absorption characteristic of the sample 8 while changing the irradiation intensity per unit time of light. The light absorption characteristic can be measured based on an emission amount of photoelectrons detected by the photoelectron detector 91 or a photovoltaic current measured by the photovoltaic current measuring device 92. A relation between the emission amount of the photoelectrons and a light absorption amount, or a relation between the photovoltaic current and the light absorption amount may, for example, be measured in advance and the measurement result may be stored in the storage device 27.

### (FIG. 10: Step S1002)

The signal corrector 94 corrects the detection signal of the secondary electrons based on the light absorption characteristic measured in S1001. That is, the influence of the light irradiation on the secondary electron detection signal is removed by subtracting the secondary electron detection signal when the sample 8 is irradiated with the light and not irradiated with the electron beam from the secondary electron detection signal when the sample 8 is irradiated with the electron beam and light. The secondary electron detection signal when the sample 8 is irradiated with the light and not irradiated with the electron beam can be acquired from the detection result in S1001.

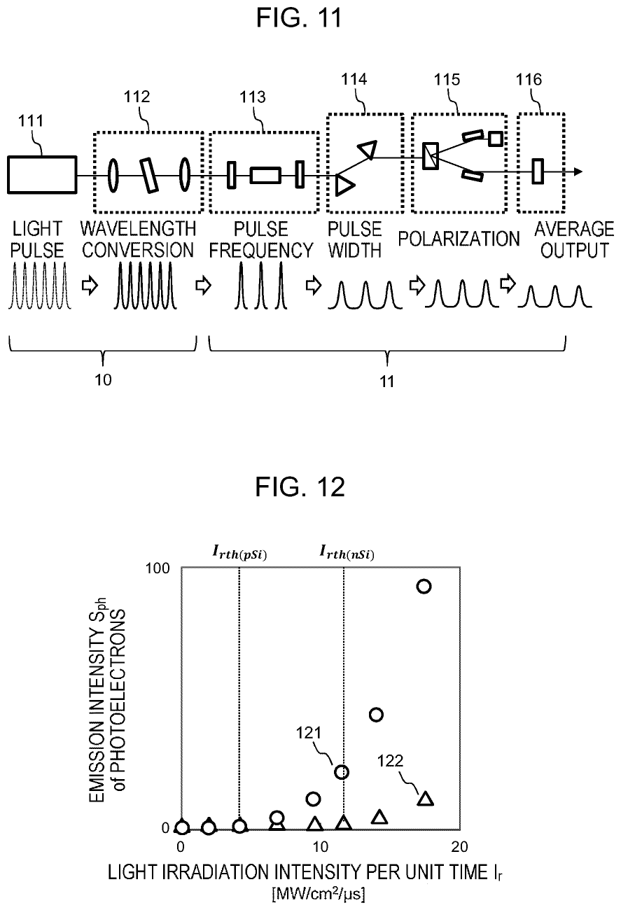

FIG. 11 is a configuration diagram of the pulse laser 10 and the light intensity adjusting unit 11 in the second embodiment. A laser oscillator (or laser amplifier) 111 emits the light pulse. A wavelength converter 112 is configured with a non-linear optical element and the like, and controls the wavelength of the light pulse. A pulse picker 113 is configured with an electro-optic effect device and a magneto-optic effect device, and controls the frequency of the light pulse. A pulse dispersion controller 114 is configured with a pair of prisms and the like, and controls the pulse width of the light pulse. A polarization controller 115 is configured by using a birefringent element or the like, and controls a polarization plane of the light pulse. An average output controller 116 is configured with a neutral density (ND) filter or the like whose density can be changed, and adjusts the average output of the light pulse. Further, the light pulse introduction unit 12 can be configured with a zoom lens or the like, so that an irradiation diameter of the light pulse can be controlled.

FIG. 12 is an example of a relation between the light absorption characteristic measured in S1001 and the light irradiation intensity per unit time. Here, absorption characteristics of P-type silicon and N-type silicon which have different types of impurities are analyzed. The measurement is carried out by detecting the photoelectrons using the photoelectron detector 91. In this case, the electron beam is blocked by the circuit breaker 93. The wavelength of the light pulse is 405 nm. At this wavelength, there is no light energy (eV) that reaches a vacuum level of silicon, and thus the photoelectrons are not emitted when the light pulse is linearly absorbed. As the light irradiation intensity per unit time increases, the photoelectrons are emitted through the multiphoton absorption, which is a non-linear process.

FIG. 12 shows a relation between the light irradiation intensity Ir per unit time and an emission intensity Sph of the photoelectrons in the P-type silicon and the N-type silicon. P-type silicon 121 emits the photoelectrons with a light irradiation intensity per unit time of 4 MW/cm2/μs as a threshold, whereas N-type silicon 122 emits the photoelectrons with a threshold of 12 MW/cm2/μs. FIG. 12 shows an example of the photoelectrons detected by using the photoelectron detector 91, but when the photovoltaic current measuring device 92 is used, the photovoltaic current emitted from the sample 8 can be measured, and thus the same thresholds as in FIG. 12 can be extracted.

FIG. 13 is an example of a cross-sectional view of the sample 8. N-type silicon 132 is joined and formed on a surface of P-type silicon 131, and a hole pattern of a silicon oxide film 133 is further formed on the surface. A defect 134 is a portion where the N-type silicon 132 and the hole pattern of the silicon oxide film 133 are out of alignment.

In the second embodiment, the same GUI as in the first embodiment is used. SEM observation conditions include an acceleration voltage of 1.0 kV, an irradiation current of 500 pA, an observation magnification of 200 K times, and a scanning speed of twice the TV scanning speed. 0.0 MW/cm2/μs is made as the condition a of the light irradiation intensity per unit time. 4 MW/cm2/μs is made as the condition b. 12 MW/cm2/μs is made as the condition c. The condition b further includes a light pulse frequency of 100 MHz, an average output of 16 mW, a pulse width of 1000 femtoseconds, and an irradiation diameter of 50 μm. The condition c further includes a light pulse frequency of 50 MHz, an average output of 54 mW, a pulse width of 800 femtoseconds, and an irradiation diameter of 60 μm.

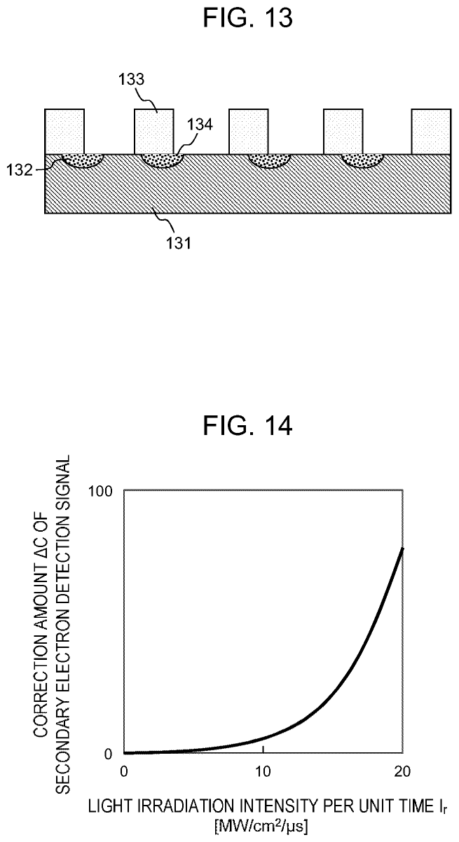

FIG. 14 is a graph showing a relation of a correction amount ΔC of the secondary electron detection signal with respect to the light irradiation intensity per unit time in the second embodiment. The correction amount ΔC is determined by an area ratio of the P-type silicon 131 to the N-type silicon 132 in the sample 8 in addition to the relation between the light irradiation intensity Ir per unit time and the emission intensity Sph of the photoelectrons shown in FIG. 12. In the second embodiment, the ratio is set to 50%.

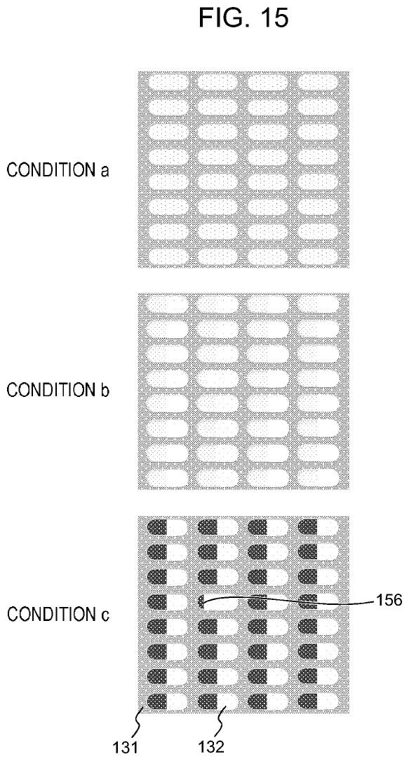

FIG. 15 is an example of observation images acquired under three conditions of the light irradiation intensity per unit time. In the observation image acquired under the condition a, the P-type silicon 131 and the N-type silicon 132 show the same image brightness, the visibility of the pattern is low, and the defect portion cannot be visually recognized. In the observation image acquired under the condition b, the visibility of the P-type silicon 131 and the N-type silicon 132 is improved, but a defect detection is insufficient. In the observation image acquired under the condition c, the image brightness of the P-type silicon 131 is low, and the pattern contrast is the highest. A defect 156 can be sufficiently visually recognized if the observation image is acquired under the condition c.

As a method for removing the influence of photoelectrons from the secondary electron signal, by controlling a voltage applied to an energy filter included in the electron lens control unit 16, the influence of photoelectrons may be removed from the secondary electron signal detected by the electron detector 5.

### Overview of Second Embodiment

The charged particle beam apparatus 1 according to the second embodiment corrects the secondary electron detection signal by removing, from the secondary electron detection signal, the influence of the photoelectrons emitted from the sample 8 by irradiating the sample 8 with the light. As a result, the contrast of the observation image of the sample 8 can be formed more accurately, so that the visibility of the defect and the pattern can be improved.

### Third Embodiment

In a third embodiment of the invention, an example of intermittently irradiating the sample 8 with the electron beam is described. The visibility of the sample 8 can be improved by comparing the observation image when the electron beam is emitted with the observation image when the electron beam is not emitted. The configuration of the charged particle beam apparatus 1 is the same as that according to the second embodiment. By blocking the electron beam with the circuit breaker 93, an irradiation period and a non-irradiation period (interval period) of the electron beam can be controlled.

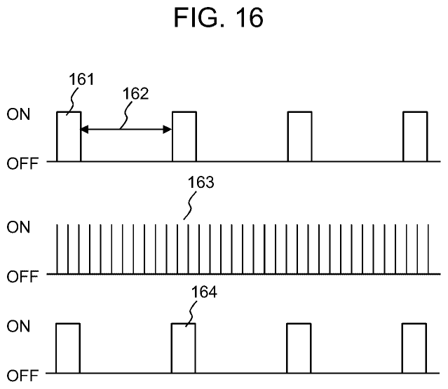

FIG. 16 is a time chart showing an electron beam irradiation timing/a pulse laser irradiation timing/a secondary electron detection timing, respectively. The control transmission unit 22 controls an irradiation period 161 and an interval period 162 of the electron beam by controlling the circuit breaker 93. In the third embodiment, a light pulse 163 of the pulse laser is controlled at a constant frequency regardless of the irradiation period 161 and the interval period 162. The light pulse 163 may be emitted in synchronization with the irradiation period 161 or may be emitted in synchronization with the interval period 162. A timing 164 for detecting the secondary electrons is synchronized with the irradiation period 161. The timing 164 for detecting the secondary electrons needs to be synchronized with the irradiation period 161 in consideration of a traveling time of the secondary electrons and a delay time based on a circuit delay of the electron detector 5.

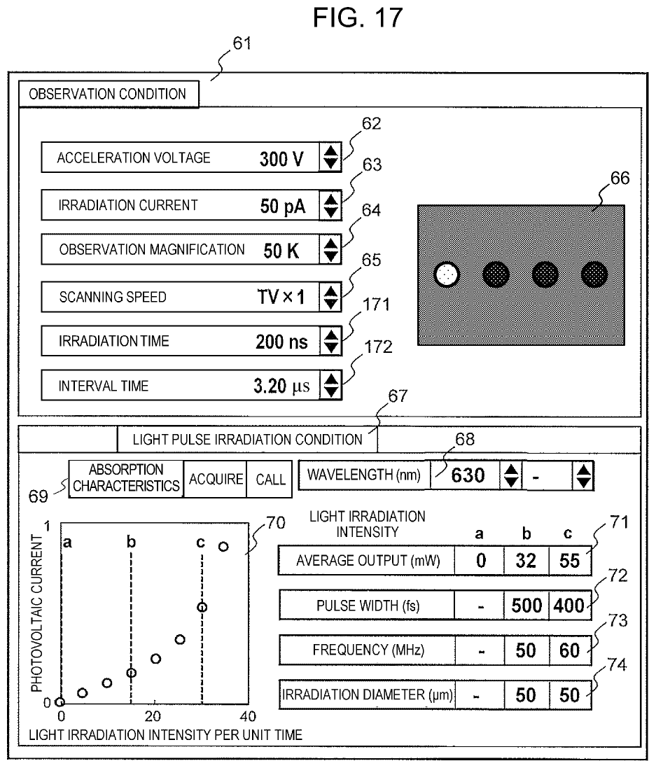

FIG. 17 is an example of the GUI 61 displayed by the image display unit 25 in the third embodiment. In the third embodiment, in addition to the GUI 61 described in the first embodiment, an irradiation period setting unit 171 and an interval period setting unit 172 are added.

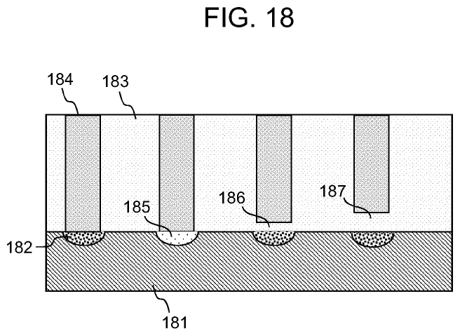

FIG. 18 is an example of a cross-sectional view of the sample 8. N-type silicon 182 is joined and formed on the surface of P-type silicon 181. The silicon oxide film 183 is provided on the surface and the hole pattern is formed in the silicon oxide film 183. A contact plug 184 of polysilicon is formed in the hole pattern. A defect 185 is injected with the N-type silicon of a high density. A defect 186 has a thin residual film between the contact plug 184 and the N-type silicon 182. A defect 187 has a thicker residual film than that of the defect 186.

In the third embodiment, the observation conditions include an acceleration voltage of 0.3 kV, an irradiation current of 50 pA, an observation magnification of 50 K times, and a scanning speed of TV scanning speed. When emitting the electron beam intermittently, an irradiation time is 200 ns and an interval time is 3.2 μs. In the third embodiment, a relation between the light absorption characteristic of the sample 8 and the light irradiation intensity per unit time is acquired by using the photovoltaic current measuring device 92. As shown in the absorption characteristic display unit 70 in FIG. 17, the conditions a to c are set as the light irradiation intensities per unit time based on the absorption characteristics. The condition a is 0.0 MW/cm2/μs. The condition b is 16 MW/cm2/μs. The condition c is 30 MW/cm2/μs. Conditions corresponding to these conditions are set in the irradiation condition setting unit 67.

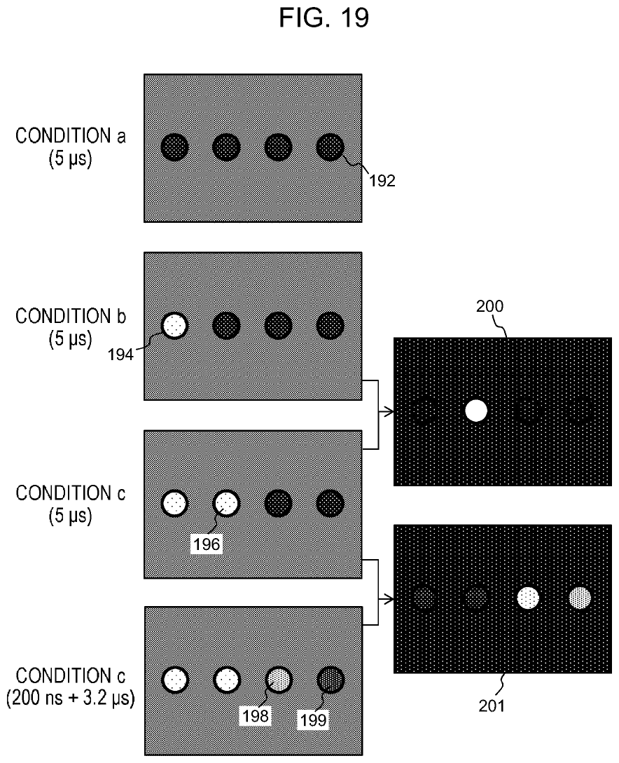

FIG. 19 is an example of observation images acquired by the electron beam under irradiation conditions. In the observation image acquired by continuously irradiating the sample with the electron beam for 5 μs or more under the condition a, the contact plug 192 can be identified, but the defect cannot be identified. In the observation image acquired by continuously irradiating the sample with the electron beam for 5 μs or more under the condition b, a depletion layer of junction comes into conductive due to linear absorption of the light pulse, so that a normal contact plug 194 becomes bright. However, a defect having the N-type silicon of a high density with weak linear absorption (the defect 185 in FIG. 18) and defects with residual film (defects 186 and 187 in FIG. 18) are charged by being irradiated with the electron beam, and thus brightness of the contact plug remains low. In the observation image acquired by continuously irradiating the sample with the electron beam for 5 μs or more under the condition c, the depletion layer of the junction having the N-type silicon of a high density is also made conductive by the non-linear absorption, and thus a defect 196 becomes bright. In the observation image acquired by continuously being intermittently irradiated for an irradiation time of 200 ns and an interval time of 3.2 μs of the electron beam under the condition c, a defect 198 which has a thin residual film between the contact plug and the N-type silicon and a defect 199 which has a thicker residual film than that of the defect 198 can be recognized as a grayscale contrast. Under this condition, the defect 198 with a high capacitance is brighter than the defect 199 with a low capacitance.

A difference image 200 is formed by a difference between the two observation images (condition b: 5 μs) (condition c: 5 μs) in the middle of FIG. 19. From the difference image 200, the defect of the junction on the bottom of the contact plug can be extracted. A difference image 201 is formed by a difference between the two observation images (condition c: 5 μs) (condition c: 200 ns) in the lower part of FIG. 19. From the difference image 201, the residual film defects having different film thicknesses on the bottom of the contact plug can be extracted.

### Overview of Third Embodiment

The charged particle beam apparatus 1 according to the third embodiment generates an observation image while intermittently irradiating the sample 8 with the electron beam by switching between a period in which the sample 8 is irradiated with the electron beam and a period in which the sample is not irradiated with the electron beam. As a result, it is possible to acquire an observation image having a contrast different from an observation image acquired while continuously irradiating the sample 8 with an electron beam. In this way, an electrical defect having different electrical characteristics can be discriminated and detected.

### Fourth Embodiment

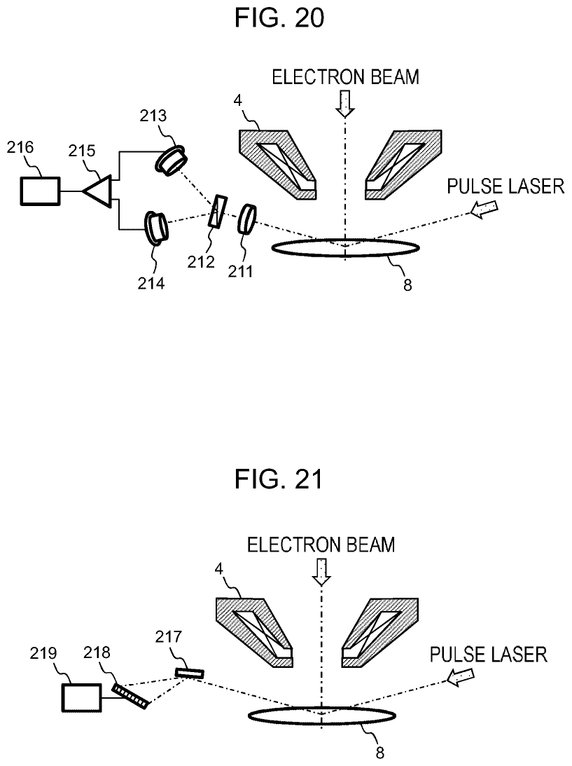

FIG. 20 is a configuration example of the absorption characteristic measuring unit 13. Here, a configuration for detecting a polarization plane of light is shown. The light pulse reflected by the sample 8 is elliptically polarized by a wave plate 211, and is divided into an S-polarized light and a P-polarized light by a birefringent element 212. A photodetector 213 detects a light intensity of the S-polarized light, and a photodetector 214 detects a light intensity of P-polarized light. A subtractor 215 calculates a difference between the light intensity of the S-polarized light and the light intensity of the P-polarized light. A signal detector 216 converts the calculation result into data as an intensity of elliptically polarized lights. A digital processing may be used instead of an analog circuit to acquire a difference signal.

FIG. 21 is a configuration example of the absorption characteristic measuring unit 13. Here, a configuration for detecting a harmonic generated by the non-linear absorption is shown. A harmonic light pulse generated in the sample 8 is spectrally decomposed by a diffraction grating 217. A light intensity for each spectrum is detected by a light intensity sensor 218 having a plurality of detection elements made by a silicon process on a line. The light intensity of each wavelength acquired by the light intensity sensor 218 is converted into data by a signal detector 219. In the fourth embodiment, a light pulse to be emitted is a circularly polarized light, and a wavelength is 700 nm. The threshold of the light irradiation intensity per unit time at which the linear is changed into the non-linear is an irradiation intensity at which the light pulse is changed into the elliptically polarized light or an irradiation intensity at which a second harmonic with 350 nm is generated.

In the fourth embodiment, the flowchart in FIG. 3 and the GUI in FIG. 6 are used. As a sample in the fourth embodiment, a sample formed by an organic-inorganic hybrid material in which a dielectric is mixed with an organic substance is used. According to the threshold of the light irradiation intensity per unit time at which the polarization plane from the sample 8 changes due to the light pulse irradiation or the second harmonic is generated, the condition a to the condition c are set as the light irradiation intensity per unit time. The condition a is 0.0 MW/cm2/μs. The condition b is 4 MW/cm2/μs. The condition c is 10 MW/cm2/μs. The condition b further includes the light pulse frequency of 100 MHz, an average output of 14 mW, a pulse width of 220 femtoseconds, and an irradiation diameter of 100 μm. The condition c further includes the light pulse frequency of 100 MHz, an average output of 35 mW, the pulse width of 220 femtoseconds, and the irradiation diameter of 100 μm.

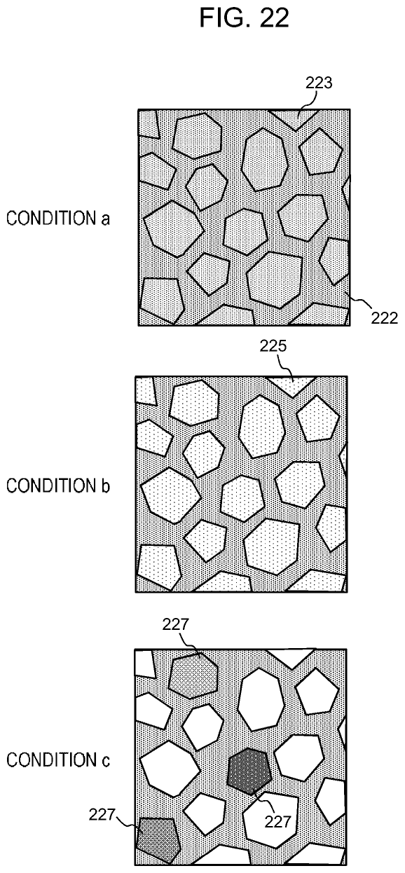

FIG. 22 is an example of observation images acquired under the three conditions of the light irradiation intensity per unit time. In the observation image acquired under the condition a, an organic substance 222 and a dielectric 223, which are bases of a hybrid material, show the same image brightness, and visibility of a dielectric domain is low. In the observation image acquired under the condition b, the dielectric is excited by the linear absorption, so that secondary electrons emitted from a dielectric 225 increase, and the dielectric domain can be clearly seen. In the observation image under the condition c, the non-linear absorption occurs in each of the dielectrics having different complex dielectric constants, so that the emission of the secondary electrons is reduced. In the observation image acquired under the condition c, dielectrics 227 having different complex dielectric constants can be inspected on a gray scale according to a difference in the complex dielectric constants.

According to the charged particle beam apparatus 1 according to the fourth embodiment, domains having different dielectric constants of the sample 8 can be discriminated and detected. In the fourth embodiment, two configuration examples for detecting the polarization plane and the wavelength are shown as the absorption characteristic measuring unit 13, but it is unnecessary to detect both of the two characteristics, and the polarization plane may be detected or the wavelength may be detected.

### Fifth Embodiment

In a fifth embodiment of the invention, in addition to the configurations described in the first to fourth embodiments, a configuration example in which the contrast of the observation image is enhanced by energy discrimination of the secondary electrons is described. Other configurations are the same as those in the first to fifth embodiments.

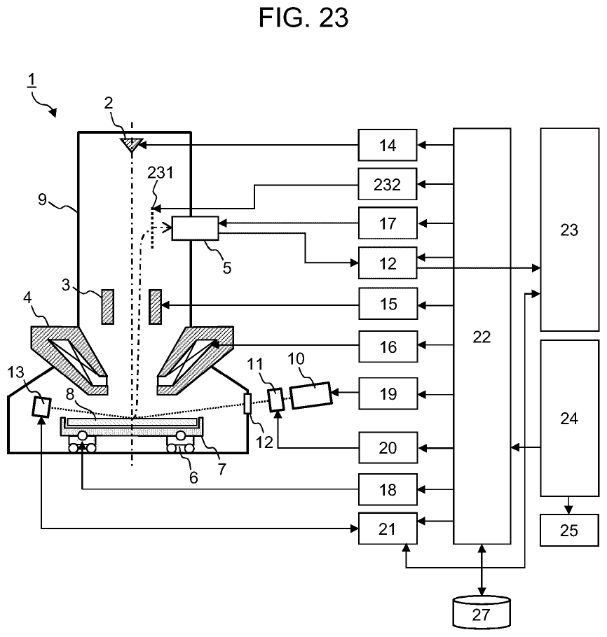

FIG. 23 is a configuration diagram of the charged particle beam apparatus 1 according to the fifth embodiment. Here, in addition to the configuration described in the first embodiment, a configuration example including an energy filter 231 that discriminates an energy of the secondary electrons and an energy filter control unit 232 that controls a voltage applied to the energy filter 231 is shown. The user specifies a voltage to be applied to the energy filter 231 via the operation interface 23, and the energy filter control unit 232 controls the voltage according to the specification. An energy spectrometer such as a spectrum meter using a Wien filter can be used instead of the energy filter 231.

In the fifth embodiment, the sample 8 shown in FIG. 7 is used. The observation conditions include the acceleration voltage of 0.5 kV, the irradiation current of 100 pA, the observation magnification of 100 K times, and the scanning speed of the TV scanning speed. The wavelength of the light pulse is 355 nm. As for the light irradiation intensity per unit time, the condition a and the condition b are set as the light irradiation intensities based on the relation between the absorption characteristic and the light irradiation intensity per unit time as in the first embodiment. 0 MW/cm2/μs is made as the condition a and 350 MW/cm2/μs is made as the condition b. Further, the average outputs are adjusted based on the two set conditions of the light irradiation intensity per unit time. The average outputs are 0 mW and 220 mW, respectively.

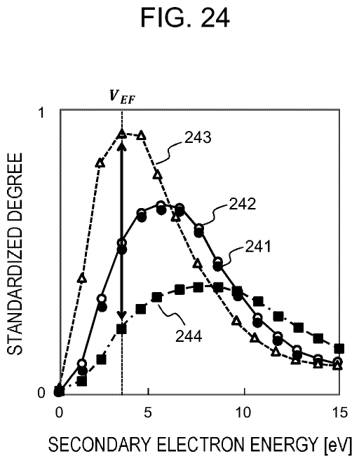

FIG. 24 is a graph showing an energy distribution of the secondary electrons when a light pulse is emitted according to the light irradiation intensities. In the light pulse of 0 MW/cm2/μs (that is, no light irradiation), almost no difference exists between silicon 241 and silicon nitride 242. When the light pulse of 350 MW/cm2/μs is emitted, the silicon nitride is in a linear absorption state, and an emission efficiency of the secondary electrons is high. It can be seen that in an energy distribution of secondary electrons of silicon nitride 243 in this state, a peak intensity is high and a peak is shifted to a low energy side. Silicon irradiated with the light pulse 350 MW/cm2/μs is in a non-linear absorption state, and emission of the secondary electrons is suppressed. It can be seen that in an energy distribution of secondary electrons of silicon nitride 244 in this state, a peak intensity is low and a peak is shifted to a high energy side. From FIG. 24, it can be seen that in addition to the difference in the emission efficiencies of the secondary electrons, a difference in secondary electron yields can be expanded by the energy filter 231. In the fifth embodiment, a filter voltage VEF is set to 4V.

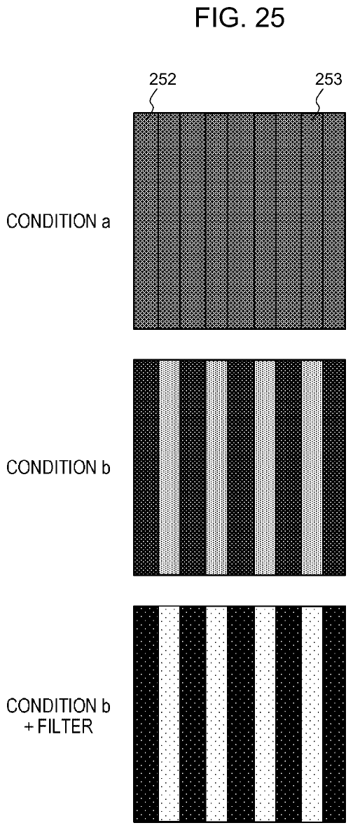

FIG. 25 is an example of observation images acquired by the energy filter 231 under two conditions of the light irradiation intensity per unit time. In the observation image acquired under the condition a, silicon 252 and silicon nitride 253 show the same image brightness, and the visibility of the pattern is low. In the observation image acquired under the condition b, a difference in the image brightness between the silicon 252 and the silicon nitride 253 is widened, and the visibility of the pattern is improved. In the observation image acquired by using the energy filter 231 (filter voltage is 4V) under the condition b, it can be seen that an image contrast between the silicon 252 and the silicon nitride 253 is enhanced by the energy discrimination, and the visibility of the pattern is further improved.

### Overview of Fifth Embodiment

According to the charged particle beam apparatus 1 according to the fifth embodiment, in addition to adjusting the light irradiation intensities per unit time described in the first to fourth embodiments, the contrast of the observation image can be enhanced by using the energy discrimination of the secondary electrons.

### Sixth Embodiment

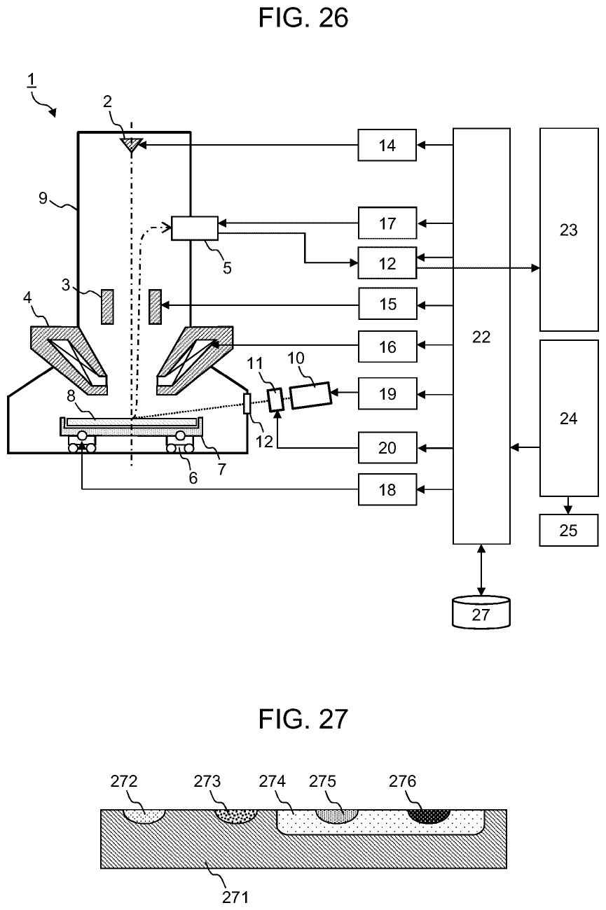

FIG. 26 is a configuration diagram of the charged particle beam apparatus 1 according to a sixth embodiment of the invention. The sixth embodiment describes a configuration example for identifying the characteristic of the sample 8 by using the secondary electron detection signal or the observation image itself instead of using the absorption characteristic measuring unit 13 and the absorption characteristic measurement control unit 21. A configuration shown in FIG. 26 is the same as the configuration described in the first embodiment except that the absorption characteristic measuring unit 13 and the absorption characteristic measurement control unit 21 are not provided.

In the sixth embodiment, the condition a and the condition b are set as the conditions of the light irradiation intensity per unit time. The condition a is 10.0 MW/cm2/μs. The condition b is 100 MW/cm2/μs. The condition a further includes an average output of the light pulse of 400 mW. The condition b further includes an average output of the light pulse of 4000 mW.

FIG. 27 is an example of a cross-sectional view of the sample 8. N-type silicon 272 with a low density and N-type silicon 273 with a high density are formed on a surface of P-type silicon 271. An N-type silicon well 274 with a low density is further formed on the surface of the P-type silicon 271. P-type silicon 275 with a low density and P-type silicon 276 with a high density are formed on a surface of the N-type silicon well 274.

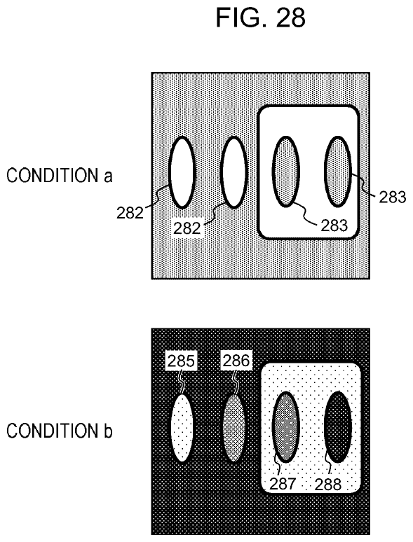

FIG. 28 is an example of observation images acquired under two conditions of the light irradiation intensity. In the observation image acquired under the condition a, N-type silicon 282 and P-type silicon 283 can be clearly distinguished. From the observation image acquired under the condition a, types of impurities and an energy band of a material can be known. In the observation image acquired under the condition b, a difference in density can be distinguished from a difference in image brightness of N-type silicon 285 with a low density and N-type silicon 286 with a high density. Similarly, P-type silicon 287 with a low density and P-type silicon 288 with a high density can be distinguished from a difference in the image brightness. From the observation image acquired under the condition b, a density of the impurities and an electronic state of the material can be known.

According to the charged particle beam apparatus 1 according to the sixth embodiment, different types of the characteristics of the sample 8 can be discriminated and visualized from the observation images acquired under different conditions of the light irradiation intensity per unit time.

### Modifications of Invention

The invention is not limited to the embodiments described above, and includes various modifications. For example, the embodiments described above have been described in detail for easily understanding the invention, and the invention is not necessarily limited to those including all the configurations described above. In addition, a part of the configuration of one embodiment can be replaced with the configuration of another embodiment, and the configuration of another embodiment can be added to the configuration of one embodiment. A part of the configuration of each of the embodiments may be added to, deleted from, or replaced with another configuration.

In the embodiments described above, one or more wavelengths can be selected by using, as the pulse laser 10, a tunable laser whose wavelength can be selected by parametric oscillation. A single wavelength pulse laser may be used, or a wavelength conversion unit that generates a harmonic of light may be used. Since an image with a uniform image contrast can be acquired in an irradiation region of the light pulse, the irradiation region of the light pulse is desired to be wider than a deflection region of the electron beam controlled by the deflector 3, but the invention is not limited to a difference between the irradiation region of the light pulse and the deflection region. The light pulse and the electron beam may be emitted simultaneously in time, or may be emitted at different timings in time.

In the embodiments described above, the ND filter capable of changing a density for controlling an average output of a laser can be used as the light intensity adjusting unit 11. In addition, an optical attenuator can be used as an optical system for controlling an average output. The following can also be used as the light intensity adjusting unit 11: (a) a pulse picker or the like that uses the electro-optic effect device and the magneto-optic effect device and is used to control a frequency of pulses and an irradiation number of the pulses; (b) a pulse dispersion control optical system or the like that is configured with a pair of prisms and is used to control a pulse width; and (c) a condenser lens that is used to control an irradiation region of a light pulse. In addition, an optical branching device, a pulse stacker, a light wavelength conversion device, a polarization control device, and the like can also be used. These devices can be used in combination.

FIG. 2 illustrates that an absorption intensity is obtained from a difference signal between an irradiation light and a reflection light as the light absorption characteristic, but the light intensity of the reflection light may be used. In order to acquire the difference signal, a difference may be obtained by the digital processing instead of the analog circuit.

In the second embodiment, the photoelectron detector 91 can be shared with the electron detector 5. In the second embodiment, the photoelectron detector 91 and the photovoltaic current measuring device 92 are used in combination as means for measuring the photoelectrons from the sample 8, but only one of them may be used. As the absorption characteristic measuring unit 13, a reflection light detector of the relection light from the sample 8, a polarization plane detector of the reflection light from the sample 8, a wavelength detector of the reflection light from the sample 8, and the like can also be used.

The circuit breaker 93 can be configured with an electron beam blocking portion including a parallel electrode and a diaphragm. In the deflector 3, the electron beam may be blocked, or a shield such as a valve on an optical axis of the electron beam may be operated.

In the embodiments described above, the control transmission unit 22 can be configured by using hardware such as a circuit device where a function is implemented, or can be configured by using a computing device to execute software where a function is implemented. The same applies to the functional units (the electron gun control unit 14, the deflection signal control unit 15, the electron lens control unit 16, the detector control unit 17, the stage position control unit 18, the pulse laser control unit 19, the light intensity adjustment control unit 20, the absorption characteristic measurement control unit 21, and the like) controlled by the control transmission unit 22. The same applies to the image forming unit 24.

In the embodiments described above, the example in which the charged particle beam apparatus 1 is configured as the scanning electron microscope has been described as the configuration example for acquiring the observation images of the sample 8, but the invention can also be used in other charged particle beam apparatuses. That is, the invention can be applied to other charged particle beam apparatuses that adjust an emission efficiency of secondary charged particles by irradiating the sample 8 with light.

### REFERENCE SIGN LIST

1 charged particle beam apparatus
2 electron gun
3 deflector
4 electron lens
5 electron detector
6 XYZ stage
7 sample holder
8 sample
9 housing
10 pulse laser
11 light intensity adjusting unit
12 light pulse introduction unit
13 absorption characteristic measuring unit
14 electron gun control unit
15 deflection signal control unit
16 electron lens control unit
17 detector control unit
18 stage position control unit
19 pulse laser control unit
20 light intensity adjustment control unit
21 absorption characteristic measurement control unit
22 control transmission unit
23 operation interface
24 image forming unit
25 image display unit
30 beam splitter
31 irradiation light detector
32 reflection light detector
33 subtractor
34 signal detector
51 silicon
52 silicon nitride
61 GUI
66 image display unit
67 irradiation condition setting unit
68 wavelength setting unit
69 absorption characteristic analysis unit
70 absorption characteristic display unit
75 silicon
76 silicon nitride
91 photoelectron detector
92 photovoltaic current measuring device
93 circuit breaker
94 signal corrector
111 laser oscillator (or laser amplifier)
112 wavelength converter
113 pulse picker
114 pulse dispersion controller
115 polarization controller
116 average output controller
121 P-type silicon
122 N-type silicon
131 P-type silicon
132 N-type silicon
133 silicon oxide film
134 defect
152 P-type silicon
153 N-type silicon
156 defect
161 irradiation period
162 interval period
163 light pulse
171 irradiation period setting unit
172 interval period setting unit
181 P-type silicon
182 N-type silicon
183 silicon oxide film
184 contact plug
185 defect
186 defect
187 defect
192 contact plug
194 contact plug
196 defect
198 defect
199 defect
200 difference image
201 difference image
211 wave plate
212 birefringent element
213 photodetector
214 photodetector
215 subtractor
216 signal detector
217 diffraction grating
218 light intensity sensor
219 signal detector
222 organic substance
223 dielectric
225 dielectric
227 dielectric
231 energy filter
232 energy filter control unit
252 silicon
253 silicon nitride
271 P-type silicon
272 N-type silicon
273 N-type silicon
274 N-type silicon well
275 P-type silicon
276 P-type silicon
282 N-type silicon
283 P-type silicon
285 N-type silicon
286 N-type silicon
287 P-type silicon
288 P-type silicon

1. A charged particle beam apparatus that irradiates a sample with a charged particle beam, comprising:
a charged particle source configured to irradiate the sample with primary charged particles;
a light source configured to emit light to be emitted to the sample;
a detector configured to detect secondary charged particles generated from the sample by irradiating the sample with the primary charged particles;
an image processing unit configured to generate an observation image of the sample by using the secondary charged particles detected by the detector; and
a light intensity control unit configured to adjust an irradiation intensity per unit time of the light, wherein
the light intensity control unit causes the image processing unit to generate a plurality of the observation images having different contrasts by changing the irradiation intensity per unit time of the light.

2. The charged particle beam apparatus according to claim 1, wherein
the sample has a characteristic that an emission amount of the secondary charged particles changes according to the irradiation intensity per unit time of the light,
the light intensity control unit controls the irradiation intensity per unit time of the light to a first intensity such that the sample emits the secondary charged particles with a first emission amount corresponding to the first intensity, and then causes the image processing unit to generate the observation images, and
the light intensity control unit controls the irradiation intensity per unit time of the light to a second intensity which is different from the first intensity such that the sample emits the secondary charged particles with a second emission amount corresponding to the second intensity, and then causes the image processing unit to generate the observation images.

3. The charged particle beam apparatus according to claim 2, wherein
the light intensity control unit controls the irradiation intensity per unit time of the light to a third intensity between the first intensity and the second intensity such that the sample emits the secondary charged particles with a third emission amount corresponding to the third intensity, and then causes the image processing unit to generate the observation images, and
the third emission amount is larger than the first emission amount, and the second emission amount is smaller than the first emission amount.

4. The charged particle beam apparatus according to claim 3, wherein
an absorption amount of the light absorbed by the sample has a first component proportional to a first power of the irradiation intensity per unit time of the light and a second component proportional to a second or higher power of the irradiation intensity per unit time of the light,
the second component becomes equal to or greater than the first component when the irradiation intensity per unit time of the light is equal to or greater than the third intensity, and becomes less than the first component when the irradiation intensity per unit time of the light is less than the third intensity,
the light intensity control unit sets the irradiation intensity per unit time of the light to the second intensity such that in the absorption amount, the second component becomes greater than the first component, and
the light intensity control unit sets the irradiation intensity per unit time of the light to the first intensity such that in the absorption amount, the first component becomes greater than the first component.

5. The charged particle beam apparatus according to claim 3, wherein
an absorption amount of the light absorbed by the sample has a first component proportional to a first power of the irradiation intensity per unit time of the light and a second component proportional to a second or higher power of the irradiation intensity per unit time of the light, and
the light intensity control unit controls the irradiation intensity per unit time of the light such that in the absorption amount, the second component becomes greater than the first component, such that the emission amount becomes smaller than that when the first component is greater than the second component.

6. The charged particle beam apparatus according to claim 2 further comprising:
an absorption characteristic measuring unit configured to measure an absorption amount of the light absorbed by the sample; and
a storage unit configured to store correspondence relation data that describes a correspondence relation between the absorption amount measured by the absorption characteristic measuring unit and the irradiation intensity per unit time of the light, wherein
the light intensity control unit determines the first intensity and the second intensity according to the correspondence relation described in the correspondence relation data.

7. The charged particle beam apparatus according to claim 6 further comprising:
a signal amount correction unit configured to correct a signal amount of the secondary charged particles detected by the detector according to the absorption amount measured by the absorption characteristic measuring unit.

8. The charged particle beam apparatus according to claim 7, wherein
the signal amount correction unit corrects a detection result detected by the detector by subtracting, from a first signal amount of the secondary charged particles detected by the detector when the sample is irradiated with the light and the primary charged particles, a second signal amount of the secondary charged particles detected by the detector when the sample is irradiated with the light and not irradiated with the primary charged particles.

9. The charged particle beam apparatus according to claim 1, wherein
the light intensity control unit is configured to be able to switch between an irradiation period in which the sample is irradiated with the primary charged particles and an interval period in which the sample is not irradiated with the primary charged particles, and
the image processing unit generates a plurality of the observation images having different contrasts by generating a first observation image of the sample while the sample is continuously irradiated with the primary charged particles, and generating a second observation image of the sample while the sample is intermittently irradiated with the primary charged particles, while switching between the irradiation period and the interval period.

10. The charged particle beam apparatus according to claim 1 further comprising:
an energy filter configured to discriminate the secondary charged particles incident on the detector according to an energy of the secondary charged particles.

11. The charged particle beam apparatus according to claim 1, wherein
the light intensity control unit controls one or more parameters of an average output of the light, a peak intensity of the light, a pulse width of the light, an irradiation cycle of a pulse of the light, an irradiation area of the light on a surface of the sample, a wavelength of the light, and a polarization of the light.

12. The charged particle beam apparatus according to claim 1, wherein
the light intensity control unit is configured with any one or more of an optical attenuator, an optical branching device, a pulse stacker, a pulse picker, a light wavelength conversion device, a polarization control device, and a condenser lens.

13. The charged particle beam apparatus according to claim 6, wherein
the absorption characteristic measuring unit is configured with any one or more of a reflection light detector of reflection light from the sample, a polarization plane detector of reflection light from the sample, a wavelength detector of the reflection light from the sample, a photoelectron detector of photoelectrons emitted from the sample, and a photovoltaic detector of photovoltage generated in the sample.
